(19) United States
(12) Patent Application Publication
(10) Pub. No.: US 2011/0012697 A1
(43) Pub. Date: Jan. 20, 2011

(54) ELECTRO-MAGNETIC BAND-GAP STRUCTURE, METHOD FOR MANUFACTURING THE SAME, FILTER ELEMENT AND PRINTED CIRCUIT BOARD HAVING EMBEDDED FILTER ELEMENT

(76) Inventors: Koichi Takemura, Tokyo (JP); Noriaki Ando, Tokyo (JP); Tsuneo Tsukagoshi, Tokyo (JP)

Correspondence Address: Mr. Jackson Chen, 6535 N. STATE HWY 161, IRVING, TX, 75039, US

(21) Appl. No.: 12/922,307

(22) PCT Filed: Apr. 22, 2009
(86) PCT No.: PCT/JP2009/057968

§ 371 Date: Sep. 13, 2010

(30) Foreign Application Priority Data
Apr. 22, 2008 (JP) 2008-111285

(51) Int. Cl. H01P 1/203; H05K 13/00

(52) U.S. Cl. 333/212; 29/825

(57) ABSTRACT

An electromagnetic bandgap structure EBG includes a rigid substrate, a first conductive plane provided on the rigid substrate, a dielectric layer provided on the first conductive plane, and a plurality of conductor patches arrayed in a two-dimensional regular pattern on the dielectric layer. The electromagnetic bandgap structure also includes an interlayer insulation film provided on top of the conductor patches, and a second conductive plane provided on the interlayer insulation film. The conductor patches and the second conductive plane are interconnected by a plurality of conductors provided in extending through the bulk of the interlayer insulation film.

### REFERENCE TO RELATED APPLICATION

This application is the National Phase of PCT/JP2009/057968, filed Apr. 22, 2009, which is based upon and claims the benefit of the priority of Japanese patent application No. 2008-111285 filed on Apr. 22, 2008, the disclosure of which is incorporated herein in its entirety by reference thereto.

### TECHNICAL FIELD

This invention relates to an electro-magnetic bandgap structure, a filter element, a printed circuit board having an embedded filter element, and a method for producing the electro-magnetic bandgap structure.

### BACKGROUND

An electromagnetic bandgap structure, sometimes referred to below as an EBG structure, has a bandgap in a specified frequency range, and includes larger numbers of dielectric or electrically conductive members arrayed in a two-dimensional or three-dimensional regular pattern. This EBG structure has a specified frequency range termed bandgap within which propagation of an electromagnetic wave of the specified frequency range is suppressed or attenuated significantly. An antenna or a noise filter, taking advantage of such feature of the EBG structure, has recently been proposed.

Patent Document 1 has it as an object to provide a ground plane that suppresses the surface current as a concrete EBG structure. Specifically, Patent Document 1 discloses a ground plane mesh in which upper side metal patches are arranged in the mesh on top of a plate in superposition thereon. The upper side metal patches are separated from the plate by a thin dielectric spacer. In more detail, thumbtack-shaped conductor elements, made up of small pieces or patches of conductors in the shape of polygonal plate pieces, and conductor pillars, are periodically arranged on a conductive plane, and the conductor elements are connected to the conductive plane.

Patent Document 2 and Non-Patent Document 1 show a structure in which small pieces of thumbtack-shaped conductor elements structured by polygonal plate pieces and conductor pillars are periodically arranged on a conductive plane, and the conductor elements are connected to the conductive plane. Another conductive plane is layered, via a dielectric layer for facing the small pieces of conductors.

### Patent Document 1:

JP patent Kohyo Publication No. JP-P2002-510886A (summary, paragraphs 0003 and 0039, FIG. 26)

### Patent Document 2:

US 2005/0029632 (FIGS. 1, 2, paragraph 0053)

### Non-Patent Document 1:

S. D. Rodgers, “Electromagnetic-Bandgap Layers for Broad-Band Suppression of TEM Modes in Power Planes”, IEEE Trans. On Microwave Theory and Techniques, vol. 53, No. 8, August 2005, p. 2495-2505

### SUMMARY

The entire disclosures of Patent Documents 1, 2 and Non-Patent Document 1 are incorporated herein by reference thereto. The following analysis is given from the standpoint of the present invention.

The EBG structure, disclosed by Patent Document 1, may be comprehended as being a distributed constant circuit formed by a two-dimensional array of capacitances (C) between conductor patches and inductances (L) formed by conductor elements and a conductive plane. Such EBG structure forms a bandgap in a frequency range in the vicinity of 1/√LC. Hence, by properly designing the shape and/or the array of the conductor elements, it is possible to display the function of, for example, a filter that suppresses propagation of the electromagnetic wave in a desired frequency range.

The structures disclosed in Patent Document 2 and Non-Patent Document 1 may be comprehended as being a distributed constant circuit formed by a two-dimensional array of capacitances (C) between conductor patches and the conductive plane facing them and inductances (L) formed by the conductor elements and the conductive plane. This EBG structure forms a bandgap in a specified frequency band in response to the capacitances and the inductances. Thus, by properly designing the shape and/or the array of the conductor elements, it is again possible to display the function of, for example, a filter that suppresses propagation of the electromagnetic wave in a desired frequency range.

To enhance the application of this EBG structure to the field of a mobile phone, digital household electrical devices or information equipment, it becomes incumbent to reduce the size of the EBG structure to enable high density packaging. It is also incumbent to enable wide range control of the frequency band of the bandgap and in particular to allow for use of the structure in a frequency range not higher than several GHz. If attention is focused on the capacitance, the larger the capacitance, the lower is the frequency of the bandgap of the EBG structure. Hence, to increase the capacitance without increasing the area, it is crucial to decrease the electrode-to-electrode distance or to use a dielectric material having a high relative dielectric constant.

In keeping up with such tendency, Patent Document 2 and Non-Patent Document 1 disclose the desirable relationships among a separation (t2) between the conductor patches and the conductive plane facing the conductor patches, the relative dielectric constant (∈2) of the dielectric material charged in the separation (t2), a separation (t1) between the conductor patches and the conductive plane connected to the patches, and the relative dielectric constant (∈2) of the dielectric material charged in the separation (t1) in order to provide for, a wider bandwidth. Specifically, Patent Document 2 shows that the relationships such that t2<t1 and ∈2≧∈1 is desirable, while Non-Patent Document 1 shows that the relationships such that t2<<t1 and ∈2>>∈1 is desirable.

With the EBG structures, disclosed in Patent Documents 1, 2 and Non-Patent Document 1, the bandgap is truly demonstrated, however, the size of several mm square is required of the conductor patch, and hence the size of several cm square is required of the EBG structure as a whole. The EBG structure is thus difficult to package on electronic equipment. This may be due to the fact that, since the EBG structure is fabricated using the printed circuit board process and material, a dielectric material with a relative dielectric constant of 3 to 5 and a thickness not less than dozens of μms is used. If this type of the material is used, the capacitance between parallel flat electrodes, for example, is only on the order of a few pFs per mm².

In fact, in Non-Patent Document 1, it is indicated that the EBG structure is made up of larger numbers of conductor patches each being a few mm square. In Patent Document 2, it is indicated in FIGS. 1 and 2 that the EBG structure is made up of a second conductive plane, an interlayer insulating film, larger numbers of conductor patches arrayed in a regular two-dimensional pattern, a dielectric layer and a first conductive plane. The conductor patches and the second conductive plane are interconnected by a plurality of conductors provided extending through the bulk of the interlayer insulation film. However, researches conducted by the present inventors indicated that, with this layered configuration, it is not possible to reduce the size of the EBG structure. It will be observed that the thickness of the dielectric layer is to be reduced as described above as one of the methods of reducing the size of the EBG structure while the capacitance is increased. However, the dielectric layer cannot be reduced due to crests and troughs proper to the conductor patches. These crests and troughs are necessarily produced in the EBG structure in which the larger numbers of conductor patches, dielectric layer and the first conductive plane are provided in this order.

To increase the capacitance between flat parallel electrodes or the capacitance per unit area to reduce the size of the EBG structure, it may be contemplated to reduce the electrode-to-electrode distance or to use a high dielectric constant material for the dielectric layer provided between the electrodes. In terms of the concrete EBG structure, it may be beneficial to reduce the interval between the conductor patches and the first conductive plane mounted facing these conductor patches, as well as to use the high dielectric constant material for the dielectric layer provided between the conductor patches and the first conductive plane. However, no concrete means for implementing this EBG structure has not as yet been found, and hence, in the current state of the art, the size of the EBG structure may not be reduced in a desired manner.

It is therefore a primary object of the present invention to solve the above problem and to provide an EBG structure of a small size and reduced thickness having a bandgap in a specified frequency range.

It is a second object of the present invention to solve the above problem and to provide a filter element that uses an EBG structure of a small size and reduced thickness having a bandgap in a specified frequency range.

It is a third object of the present invention to solve the above problem and to provide a printed circuit board, including a filter element embedded therein, in which the filter element uses an EBG structure of a small size and reduced thickness having a bandgap in a specified frequency range.

It is a fourth object of the present invention to solve the above problem and to provide a manufacturing method for an EBG structure, according to which it is possible to manufacture an EBG structure of a small size and reduced thickness having a bandgap in a specified frequency range.

In a first aspect or mode, the present invention provides an electromagnetic bandgap structure comprising a rigid substrate, a first conductive plane provided on the rigid substrate, a dielectric layer provided on the first conductive plane, a plurality of conductor patches arrayed in a two-dimensional regular pattern on the dielectric layer, an interlayer insulation film provided on the conductor patches, and a second conductive plane provided on the interlayer insulation film, in which the conductor patches and the second conductive plane are interconnected by a plurality of conductors provided extending through the bulk of the interlayer insulation film.

In a preferred exemplary embodiment of the EBG structure of the present invention, the dielectric layer is not larger than 1 μm in thickness.

In a preferred exemplary embodiment of the EBG structure of the present invention, the dielectric layer contains an oxide of at least one element selected from the group consisting of Mg, Al, Si, Ti, Ta, Hf and Zr as a principal component.

In a preferred exemplary embodiment of the EBG structure of the present invention, the dielectric layer contains a compound oxide of metal elements as a principal component.

In a preferred exemplary embodiment of the EBG structure of the present invention, the first conductive plane includes an intermediate layer and a high melting point electrically conductive layer (an electronically conductive layer of high melting point) in this order when looking from the rigid substrate side. The intermediate layer is provided with at least one layer formed of at least one material selected from the group consisting of Ti, Ta, Cr, a nitride of Ti, a nitride of Ta and a nitride of Cr. The high melting point electrically conductive layer is formed on the intermediate layer and provided with at least one layer formed of at least one element selected from the group consisting of Pt, Pd, Ru and Ir.

In a preferred exemplary embodiment of the EBG structure of the present invention, the rigid substrate is formed of a conductor or a semiconductor.

In a preferred exemplary embodiment of the EBG structure of the present invention, the rigid substrate and the first conductive plane are electrically connected to each other.

In a preferred exemplary embodiment of the EBG structure of the present invention, the conductor or semiconductor is at least one selected from the group consisting of Si, GaAs, stainless steel, tungsten, molybdenum and titanium.

In a preferred exemplary embodiment of the EBG structure of the present invention, the rigid substrate is formed of at least one material selected from the group consisting of glass, sapphire, quartz and alumina.

In a preferred exemplary embodiment of the EBG structure of the present invention, the EBF structure further includes a backside pad provided on one of both sides of the rigid substrate that, is not provided with the first conductive plane, and a through-electrode electrically connected to the backside pad. The through-electrode extends through the bulk of the rigid substrate so as to be connected to the first conductive plane or to the second conductive plane.

In a second aspect or mode, the present invention provides a filter element comprising an electromagnetic bandgap structure as defined above, a first external connection terminal connected to the first conductive plane of the electromagnetic bandgap structure, and a second external connection terminal connected to the second conductive plane of the electromagnetic bandgap structure.

In a preferred exemplary embodiment of the filter element according to the present invention, there are provided two or more of the first external connection terminals and two or more of the second external connection terminals.

In a preferred exemplary embodiment of the filter element according to the present invention, the filter element is smaller than 1 cm² in area.

In a third aspect or mode, the present invention provides a printed circuit board having a filter element as defined above and a printed circuit board having the filter element embedded therein. The first external connection terminal of the filter element is connected to a power supply plane of the printed circuit board, and the second external connection terminal of the filter element is connected to a ground plane of the printed circuit board. Or, the first external connection terminal of the filter element is connected to the ground plane of the printed circuit board, and the second external connection terminal of the filter element is connected to the power supply plane of the printed circuit board.

In a fourth aspect or mode, the present invention provides a method for manufacturing an electromagnetic bandgap structure comprising a first conductive plane forming step of forming a first conductive plane on a rigid substrate, a dielectric layer forming step of forming a dielectric layer on the first conductive plane, a conductor patch forming step of forming a plurality of conductor patches arrayed in a regular two-dimensional pattern on the dielectric layer, an interlayer insulation layer forming step of forming an interlayer insulation layer on the conductor patches, and a second conductive plane/conductor forming step of forming a second conductive plane on the interlayer insulation layer and forming a plurality of conductors arranged through the interlayer insulation layer to interconnect the conductor patches and the second conductive plane.

In a preferred exemplary embodiment of the manufacturing method for the EBG structure according to the present invention, the thickness of the dielectric layer is set in the dielectric layer forming step so as to be not larger than 1 μm.

In a preferred exemplary embodiment of the manufacturing method for the EBG structure according to the present invention, in the dielectric layer forming step, the dielectric layer is formed using, as a principal component, an oxide of at least one element selected from the group consisting of Mg, Al, Si, Ti, Ta, I-If and Zr.

In a preferred exemplary embodiment of the manufacturing method for the EBG structure according to the present invention, in the dielectric layer forming step, the dielectric layer is formed using a compound oxide of metal elements as a principal component.

In a preferred exemplary embodiment of the manufacturing method for the EBG structure according to the present invention, in the dielectric layer forming step, the dielectric layer is formed by at least one method selected from the group consisting of a sputtering method, a CVD method, a sol/gel method, an aerosol deposition method and a spin coating method.

In a preferred exemplary embodiment of the manufacturing method for the EBG structure according to the present invention, the first conductive plane forming step includes forming an intermediate layer and a high melting point electrically conductive layer, in this order, when looking from the rigid substrate side. The intermediate layer forming step forms an intermediate layer provided with at least one layer formed of at least one material selected from the group consisting of Ti, Ta, Cr, a nitride of Ti, a nitride of Ta and a nitride of Cr. The high melting point electrically conductive layer is formed on the intermediate layer and is provided with at least one layer formed of at least one element selected from the group consisting of Pt, Pd, Ru and Ir.

In a preferred exemplary embodiment of the manufacturing method for the EBG structure according to the present invention, the rigid substrate is formed of a conductor or a semiconductor.

In a preferred exemplary embodiment of the manufacturing method for the EBG structure according to the present invention, in the first conductive plane forming step, the rigid substrate and the first conductive plane are electrically connected to each other.

In a preferred exemplary embodiment of the manufacturing method for the EBG structure according to the present invention, the conductor or semiconductor is at least one selected from the group consisting of Si, GaAs, stainless steel, tungsten, molybdenum and titanium.

In a preferred exemplary embodiment of the manufacturing method for the EBG structure according to the present invention, the rigid substrate is formed of at least one material selected from the group consisting of glass, sapphire, quartz and alumina.

In a preferred exemplary embodiment of the manufacturing method for the EBG structure according to the present invention, in the first conductive plane forming step, the first conductive plane is formed after coating a highly thermally resistant resin on the rigid substrate.

In a preferred exemplary embodiment of the manufacturing method for the EBG structure according to the present invention, the method further comprises a rigid substrate thinning/removing step of thinning or removing the rigid substrate by grinding or etching after the second conductive plane/conductor forming step.

In a preferred exemplary embodiment of the manufacturing method for the EBG structure according to the present invention, in the rigid substrate thinning/removing step, the rigid substrate is thinned or removed so that the thickness of the electromagnetic bandgap structure will be 300 μm or less.

In a preferred exemplary embodiment of the manufacturing method for the EBG structure according to the present invention, the method further comprises a step of boring a through-via in the rigid substrate and a backside pad forming step. The step of boring the through-via in the rigid substrate is carried out before the first conductive plane forming step and forms the through-via in the rigid substrate. The backside pad forming step forms a backside pad on one of both sides of the rigid substrate that is not provided with the first conductive plane.

In one aspect or mode of the present invention, there may be provided an EBG structure of a small size and thin thickness having a bandgap in a specified frequency range. Specifically, there may be provided an EBG structure of small size and thin thickness that may be surface-mounted or embedded in the bulk of the substrate as an electronic component. This is made possible because the capacitance per unit area between the first conductive plane and larger numbers of conductor patches may appreciably be increased. In addition, there may be provided an EBG structure in which the bandgap may be controlled to a frequency range lower than heretofore. This is made possible because the capacitance between the first conductive plane and the conductor patches may appreciably be increased as a result of reducing the thickness of the dielectric layer and providing for the high dielectric constant.

In one aspect or mode of the present invention, there may be provided a filter element that uses an EBG structure of small size and thin thickness having a bandgap in a specified frequency range.

In one aspect or mode of the present invention, there may be provided a printed circuit board having embedded therein a filter element that uses an EBG structure of small size and thin thickness having a bandgap in a specified frequency range.

In another aspect or mode of the present invention, there may be provided a manufacturing method for an EBG structure of a small size and thin thickness having a bandgap in a specified frequency range.

### BRIEF DESCRIPTION OF THE DRAWINGS

FIGS. 1A and 1B are a schematic perspective view and a cross-sectional view, respectively, showing Example 1 of an EBG structure according to the present invention.

FIG. 2 is a simplified equivalent circuit of the EBG structure of FIG. 1.

FIG. 3 illustrates schematic process steps showing Example 1 of the manufacturing method for an EBG structure of the present invention.

FIG. 4 is a schematic cross-sectional view of Example 2 of the EBG structure of the present invention.

FIG. 5 illustrates schematic process steps showing the manufacturing method for the EBG structure of the present invention of FIG. 4 (Example 2).

FIG. 6 is a schematic perspective view showing Example 4 of the EBG structure of the present invention.

FIG. 7 is a schematic cross-sectional view showing an Example of a filter element according to the present invention.

FIG. 8 is a schematic cross-sectional view showing an Example of a printed circuit board with an embedded filter element according to the present invention.

FIG. 9 illustrates schematic process steps showing an Example 4 of a manufacturing method for an EBG structure according to the present invention.

FIG. 10 is a schematic cross-sectional view showing Example 5 of an EBG structure according to the present invention.

FIG. 11 illustrates schematic process steps showing a manufacturing method for the EBG structure of FIG. 10 (Example 5).

FIG. 12 is a schematic cross-sectional view showing Example 3 of the EBG structure according to the present invention.

FIG. 13 illustrates schematic process steps showing a manufacturing method for the EBG structure of FIG. 12 (Example 3).

### PREFERRED MODES

Preferred Examples of the present invention will now be described. It is observed that the present invention is not limited to the Examples as now described, and may be modified in desired manner without departing from the purport of the invention.

(EBG Structure and Method for Preparing the EBG Structure)

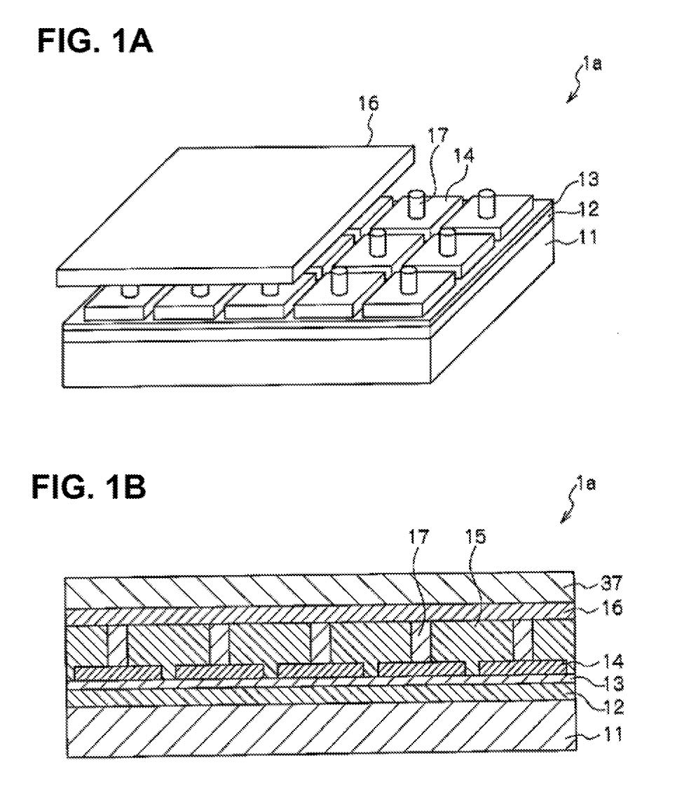

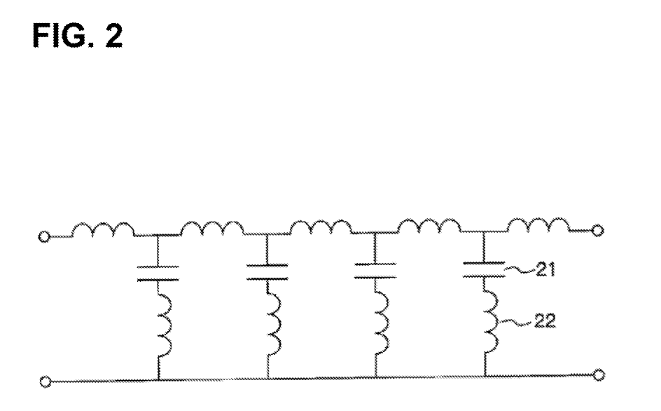

FIGS. 1A and 1B depict a schematic perspective view and a schematic cross-sectional view, respectively, showing an Example 1 of the present invention. Specifically, FIG. 1A depicts a schematic perspective view of an EBG structure 1a. For assisting in understanding the internal structure, a cover layer 37, part of a second conductive plane 16 and an interlayer insulation film 15 are omitted from the drawing. FIG. 1B depicts a schematic cross-sectional view of the EBG structure 1a. FIG. 2 depicts a simplified equivalent circuit of the EBG structure shown in FIGS. 1A and 1B.

The EBG structure 1a includes a rigid substrate 11, a first conductive plane 12 provided on the rigid substrate 11, and a dielectric layer 13 provided on the first conductive plane 12. The EBG structure also includes larger numbers of two-dimensionally arrayed conductor patches 14 provided in a regular pattern on the dielectric layer 13, and an interlayer insulating layer 15 provided on the conductor patches 14. The EBG structure further includes a second conductive plane 16 provided on the interlayer insulating layer 15. The conductor patches 14 and the second conductive plane 16 are interconnected by larger numbers of conductors 17 provided extending through the bulk of the interlayer insulating layer 15.

The EBG structure 1a includes the rigid substrate 11. On this rigid substrate 11, there is deposited a layered structure composed of the first conductive plane 12, dielectric layer 13, conductor patches 14, interlayer insulating layer 15 and the second conductive plane 16. It is thus possible to reduce the thickness of the dielectric layer 13 and the size of the EBG structure 1a. The EBG structure 1a further includes a cover layer 37 on top of the second conductive plane 16.

Viz., if, in the EBG structure 1a, it is desired to enlarge the capacitance, specifically, to increase the capacitance per unit area, as well as to reduce the size of the structure, it becomes crucial to reduce the electrode-to-electrode distance, that is, to reduce the thickness of the dielectric layer 13. Our investigations in this respect have indicated that, to form the dielectric layer to a small thickness, not the method of depositing an independent sheet, but a method of directly applying or depositing the dielectric layer 13 is more effective. However, in the EBG structure, in which the multiple conductor patches, dielectric layer and the first conductive plane are provided in this order, the dielectric layer would have to be coated or deposited on the multiple conductor patches. It is however difficult in this case to form the dielectric layer to an even thin thickness because of crests and troughs presented by the conductor patches. With this in view, the EBG structure 1a uses the rigid substrate 11 of high flatness, and the first conductive plane 12 is formed on the rigid substrate 11. By so doing, the dielectric layer 13 may be deposited on a flat surface, and hence the dielectric layer 13 may be of a small thickness. Hence, the capacitance between the first conductive plane 12 and the conductor patches 14 may be increased, with the consequence that the bandgap may be demonstrated in a lower frequency range. On the other hand, since increasing the capacitance per unit area may lead to a reduced size of the conductor patches 14, the EBG structure 1a may be reduced in area in its entirety.

In the EBG structure 1a, the first conductive plane 12 is formed on the rigid substrate 11, and faces the conductor patches 14 via the dielectric layer 13. The conductor patches 14 are arrayed in a regular two-dimensional pattern, as described above. The conductor patches 14 are connected to the second conductive plane 16 via the conductors 17. In the EBG structure 1a, capacitance elements 21 (see FIG. 2) are formed between the conductor patches 14 and the first conductive plane 12, whilst inductance elements 22 (see FIG. 2) are formed by the conductor patches 14, conductors 17 and part of the second conductive plane 16. The frequency band generating the bandgap may be controlled by these capacitances and inductances. For example, if the EBG structure 1a is used as a power supply noise suppression filter, the first conductive plane 12 and the second conductive plane 16 are connected to a power supply line and to a ground line, respectively. The noise in a desired frequency band may be suppressed by selecting the shape of the EBG structure that will give suitable values of the capacitances and inductances.

In the EBG structure 1a, the dielectric layer 13 is formed on the flat first conductive plane 12, as described above. It is thus possible to reduce the thickness of the dielectric layer 13 without regard to the thickness of the first conductive plane 12. The value of the capacitance is inversely proportional to the thickness of the dielectric layer 13. Thus, if a resin film is formed to a film thickness of 1 μm, it is possible to increase the capacitance to 50 times as high as that in case of using a resin film of 50 μm in thickness, with the area remaining the same. If the capacitance is to remain the same to generate a band gap of a frequency range desired of the EBG structure, it is possible to reduce the size of the conductor patch to a one-fiftieth. Thus, with the use of the EBG structure 1a, the dielectric layer 13 may be reduced in thickness. From the perspective of reducing the size of the EBG structure 1a, it is desirable to reduce the thickness of the dielectric layer 13 to 1 μm or less.

In the EBG structure 1a, the material types of the dielectric layer 13 or the rigid substrate 11 are not described in detail. Those material types which will be explained in the manufacturing method as later described or in connection with Example 2 may be used as appropriate.

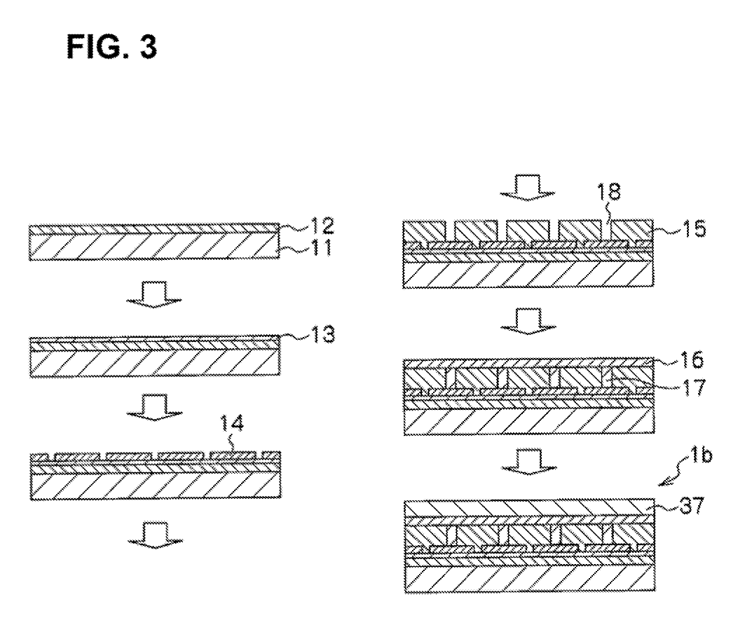

FIG. 3 depicts a schematic process showing an Example 1 of the manufacturing method for an EBG structure of the present invention. The manufacturing method for the EBG structure of the present invention includes a first conductive plane forming step of forming a first conductive plane 12 on the rigid substrate 11, and a dielectric layer forming step of forming the dielectric layer 13 on the first conductive plane 12. The manufacturing method also includes a conductor patch forming step of forming larger numbers of the conductor patches 14, arrayed in a regular two-dimensional pattern on the dielectric layer 13, and an interlayer insulating layer forming step of forming the interlayer insulating layer 15 on the conductor patches 14. The manufacturing method further includes a second conductive plane/conductor forming step of forming the second conductive plane 16 on the interlayer insulating layer 15 and forming larger numbers of conductors 17 that are provided extending through the interlayer insulating layer 15 to interconnect the conductor patches 14 and the second conductive plane 16.

In the first step, viz., conductive plane forming step, a borosilicate glass plate is used as the rigid substrate 11. A Cu (300 nm)/Ti (50 nm) stacked film is then formed on this borosilicate glass plate by a sputtering method. The stacked film is to be a substrate for plating. Then, as the first conductive plane 12, Cu is formed by electroplating to a thickness of 5 μm. TiN is then formed to a thickness of 50 nm on the surface of the resulting Cu plating layer by the sputtering method.

In the dielectric layer forming step, a silicon oxide film, 0.5 μm in thickness, is formed on the first, conductive plane 12 by a plasma CVD method to form the dielectric layer 13. To connect the first conductive plane 12 to an external circuit, a window is opened in the silicon oxide film by a photolithographic technique to expose the first conductive plane 12 to outside, in a manner not shown in FIG. 3.

In the conductor patch forming step, a stacked film of Cu (300 nm)/TiN (50 nm), operating as a substrate for plating, is formed by a sputtering method on the entire surface of the dielectric layer 13. A resist is formed thereon so as to leave conductor patches 14 and contact pads of the first conductive plane 12. The contact pads of the first conductive plane 12 are not shown in FIG. 3. Cu is then allowed to grow by electroplating to a thickness of 5 μm. The resist is then removed. The plating substrate, on which the Cu plating has not been grown, is removed by wet etching, thus forming the conductor patches 14 and the contact pads of the first conductive plane 12. These contact pads are not shown in FIG. 3.

In the interlayer insulating layer forming step, a photosensitive polyimide resin is applied to the multiple conductor patches 14 and dried in situ to deposit a film 15 μm in thickness. A number of vias 18, in which to deposit the conductors 17, are opened by a photolithographic technique to provide the interlayer insulating layer 15.

In the second conductive plane/conductor forming step, a stacked Cu (300 nm)/TiN (50 nm), operating as a substrate for plating, is deposited by the sputtering method on the entire surface of the interlayer insulation film IS and within the via 18. Then, Cu is deposited by electroplating on a flat surface part of the interlayer insulation film 15 to a thickness of 15 μm, thereby forming the second conductive plane 16. At the same time, the vias 18 in the interlayer insulation film 15 are filled with plating Cu to form the conductors 17.

Finally, the cover layer 37 is formed by resin so as to leave pads for connection to outside (not shown in FIG. 3).

In the EBG structure 1a, there is no necessity to form an underlying layer of the conductor patches 14 by patterning. Instead, it becomes possible to form the dielectric layer 13 on a surface of a first conductive plane 12 of high planarity formed on the rigid substrate 11. The dielectric layer 13 may be formed to a thinner thickness than the first conductive plane 12, as a result of which the capacitance per unit area may be increased to allow for reducing the size of the conductor patches 14. Thus, with the use of the manufacturing method according to the present invention, the thickness of the dielectric layer 13 may be reduced. It is observed that, from the perspective of reducing the size of the EBG structure 1b, it is desirable to form the thickness of the dielectric layer 13 to 1 μm or less in the dielectric layer forming step.

In the EBG structure 1b, the dielectric layer 13 is manufactured by the plasma CVD method. However, other suitable methods, such as other CVD methods, sputtering method or the spin coating method, may also be used. For forming the dielectric layer 13, polyimide or the like resin may be applied by a coating method. With the use of these methods, the dielectric layer 13 may be formed to a thinner thickness than a dielectric layer used in a process for a printed circuit board. The silicon oxide film is more beneficial in increasing the capacitance per unit area because silicon oxide is higher in relative dielectric constant than a number of other resins.

As regards the material types of the dielectric layer 13 or the rigid substrate 11, or the method for forming the dielectric layer 13, in the EBG structure 1b, the material types or the forming methods, explained later in connection with Example 2, may optionally be used.

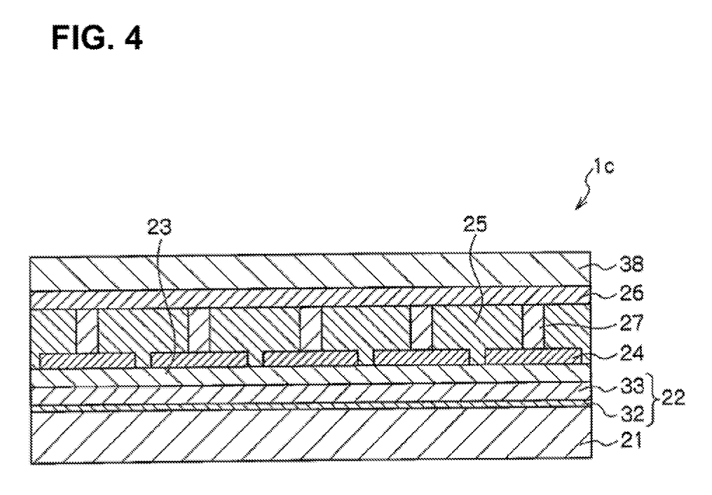

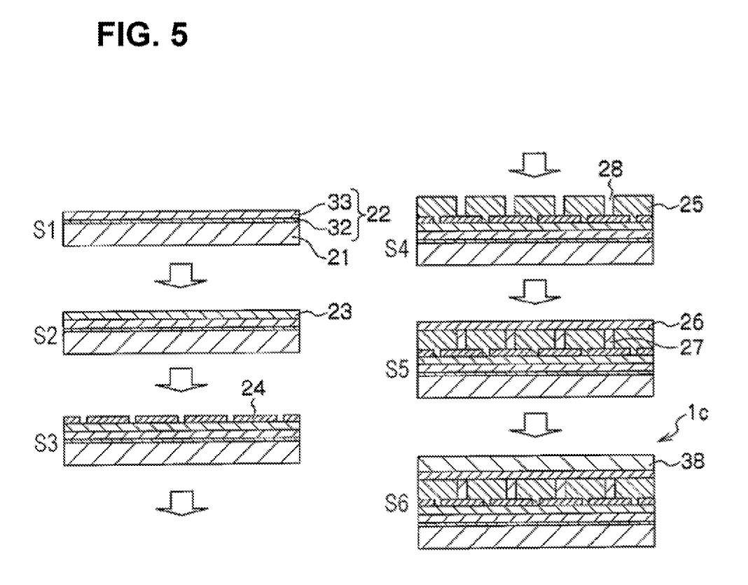

FIG. 4 depicts a schematic cross-sectional view showing Example 2 of the EBG structure of the present invention. FIG. 5 depicts a schematic process showing a manufacturing method for an EBG structure of FIG. 4 (Example 2). Specifically, a dielectric layer 23 of an EBG structure 1c is formed by a high relative dielectric constant metal oxide layer with a high relative dielectric constant not lower than several dozens.

The EBG structure 1c includes a rigid substrate 21, on which there is stacked a layered structure composed of a first conductive plane 22, a dielectric layer 23, a plurality of conductor patches 24, an interlayer insulating layer 25 and a second conductive plane 26. As the dielectric layer 23, a high relative dielectric constant metal oxide layer is used. This renders it possible to reduce the thickness of the dielectric layer 23 and hence the size of the EBG structure 1c. It is observed that the EBG structure 1c further includes a cover layer 38 on top of the second conductive plane 26.

If the EBG structure 1c is to be reduced in size as its capacitance is increased, specifically, as the capacitance per unit area is increased, it is crucial that a material with a high relative dielectric constant is used, specifically, that the dielectric layer 23 is formed of a high relative dielectric constant material. In this connection, there has so far been known a high relative dielectric constant metal oxide material with a relative dielectric constant as high as several dozens or higher. The investigations conducted by the present inventors have indicated that it is not that easy to provide such high relative dielectric constant material as the dielectric layer 23 between the first conductive plane 22 and the conductor patches 24. It may be reasoned that, if, in consideration of the film forming performance, the above mentioned high relative dielectric constant material is dispersed in resin to form a sheet, which sheet is then layered independently to form a dielectric layer, the effective relative dielectric constant is decreased as a result of mixing the material with resin and molding the resulting mixture. On the other hand, if the above mentioned high relative dielectric constant material is directly deposited on the first conductive plane 22, numerous defects may come to be contained in the dielectric layer, thus decreasing the effective relative dielectric constant. This may result from the fact that, in this case, the conductor or the resin of the printed circuit board is inferior in thermal resistance and hence the process temperature can be raised only to approximately 250° C. Thus, in the EBG structure 1c, the first conductive plane 22 and the rigid substrate 21, exhibiting thermal resistance, are used, and the dielectric layer 23 is deposited on these highly heat-resistant base layers. Since this eliminates the constraint on the process temperature to render it possible to form the dielectric layer 23 at higher temperatures, it becomes possible to form the dielectric layer 23 which is thin in thickness and which is high in relative dielectric constant. As a result, the high-quality dielectric layer 23, which is thin in thickness and high in relative dielectric constant, may be obtained, so that it is possible to increase the capacitance between the first conductive plane 22 and the conductor patches 24 to render it possible to demonstrate the bandgap in a lower frequency range. In similar manner, the fact that the capacitance per unit area is increased means that the conductor patch 24 may be reduced in size, thus allowing for reducing the overall size of the EBG structure 1c. For example, if a film of strontium titanate, with the relative dielectric constant of 120, with a film thickness being 1 μm, is used as the dielectric layer 23, it is possible to realize the capacitance of approximately 1 nF per 1 mm², which is ca. 1000 times that of a printed board material.

In the EBG structure 1c, the rigid substrate 21 is formed of a material of high thermal resistance. There is no particular limitation to this material provided that it exhibits a preset value of thermal resistance. For example, a conductor material, a semiconductor material or an insulator may be used. As the conductor and semiconductor materials, at least one selected from the group of Si, GaAs, stainless steel, tungsten, molybdenum and titanium is preferably used. If an insulator is used, the rigid substrate is preferably formed of at least one selected from the group of glass, sapphire, quartz and alumina. Out of these materials, a Si wafer is used as the rigid substrate 21 of the EBG structure 1c.

In the EBG structure 1c, the first conductive plane 22 is formed of an intermediate layer 32 exhibiting thermal resistance and a high melting point electrically conductive layer 33 similarly exhibiting thermal resistance. The intermediate layer is preferably one or more layers formed of at least one material selected from the group of Ti, Ta, Cr, a nitride of Ti, nitride of Ta and a nitride of Cr. As an example, the intermediate layer 32 of the EBG structure 1c is a four-layer structure of Ti (50 nm), TiN (50 nm), Mo (1000 nm) and Ti (50 nm). The high melting point electrically conductive layer is preferably formed of one or more elements selected from the group of Pt, Pd, Ru and Ir. As an example, the high melting point electrically conductive layer 33 of the EBG structure 1c is formed of Pt (100 nm).

In the EBG structure 1c, the dielectric layer 23 is formed as a high dielectric constant metal oxide layer. Such dielectric layer may be enumerated by a layer containing, as principal components, an oxide of at least one element selected from the group of Mg, Al, Si, Ti, Ta, Hf and Zr, and a layer containing, as principal component, a compound oxide of metal elements. It is observed that ‘a material that may become a principal component’ means such a material contained in an amount of not less than 50 atomic percent in the dielectric layer. Out of these materials, strontium titanate (with a thickness of 100 nm) is used in the dielectric layer 23 of the EBG structure 1c.

The method for manufacturing the EBG structure 1c will now be described with reference to FIG. 5.

In the first conductive plane forming step, a low-resistance Si wafer of a resistivity of 1 Ω·cm is used as the rigid substrate 21. A native oxide film on the surface of this Si wafer is removed. Then, in an intermediate layer forming step, four layers of Ti (50 nm), TiN (50 nm), Mo (1000 nm) and Ti (50 nm) are sequentially deposited on the rigid substrate 21 by the sputtering method, beginning from the lowermost layer. In addition, in a high melting point electrically conductive layer forming step, Pt (100 nm) is deposited on the intermediate layer 32 by the sputtering method as the high melting point electrically conductive layer 33. Although the low resistance Si wafer is here used as the rigid substrate 21, as an example, there is no particular limitation to the materials of the rigid substrate provided that the material used as the rigid substrate material has preset values of thermal resistance. These materials may be exemplified by conductors, semiconductors and insulators. As the conductor or the semiconductor, at least one selected from the group of Si, GaAs, stainless steel, tungsten, molybdenum and titanium may preferably be used. If the insulator is used, the rigid substrate is preferably composed of at least one material selected from the group of glass, sapphire, quartz and alumina. Although the above mentioned four-layer structure is used as the intermediate layer 32, the intermediate layer preferably includes at least one layer formed of at least one material selected from the group of Ti, Ta, Cr, a nitride of Ti, a nitride of Ta and a nitride of Cr. Although a single layer film of Pt is used for the high melting point electrically conductive layer 33, as an instance, it is preferred that the high melting point electrically conductive layer includes one or more of layers each formed of at least one element selected from the group of Pt, Pd, Ru and Ir.

In the dielectric layer forming step, strontium titanate is deposited to a thickness of 100 nm to form the dielectric layer 23, using the sputtering method. The deposition temperature is set at 450° C., while the atmosphere used for the sputtering is 80% Ar+20% O₂. Although strontium titanate as a compound oxide is here used as the dielectric layer 23, it is preferred that the dielectric layer contains, as principal component, an oxide of at least one element selected from the group of Mg, Al, Si, Ti, Ta, Hf and Zr, or a compound oxide of metal elements. The meaning of the ‘material that may become the principal component’ is as described above. Also, the sputtering method has been used for forming the dielectric layer 23 in the dielectric layer forming step. However, a CVD method, a sol-gel method, an aerosol deposition method or a spin coating method may also be used.

In the conductor patch forming step, TiN (50 nm) and Cu (300 nm) were sequentially deposited first of all on the dielectric layer 23, formed of strontium titanate, by the sputtering method. A resist mask was then photolithographically formed to a desired shape. An unneeded portion of the Cu/TiN layer was then partially removed by dry etching, in accordance with an ion milling method, thereby forming a regular two-dimensional array of a larger number of conductor patches 24.

In the interlayer insulating layer forming step, a photosensitive polyimide resin was applied onto the conductor patches 24 and dried in situ to form a film 10 μm in thickness. Vias 28 in which to deposit the conductors 27 were then photolithographically formed to form the interlayer insulating layer 25.

In the second conductive plane/conductor forming step, a stacked film of Cu (300 nm)/Ti (50 nm), acting as a substrate for plating, is formed by the sputtering method on the overall surface of the interlayer insulating layer 25 and within the vias 28. Then, Cu is deposited by electroplating to a thickness of 15 μm on a flat portion of the surface of the interlayer insulating layer 25 to form the second conductive plane 26, at the same time as the vias 28 in the interlayer insulating layer 25 were charged with Cu plating to form the conductors 27.

Finally, the cover layer 38 of resin is formed with the exception of the pads for external connection (not shown in FIG. 3).

In the EBG structure 1c, the dielectric layer 23 is formed by the sputtering method in an oxygen atmosphere at elevated temperatures. This allows for forming the dielectric layer 23 that has a high relative dielectric constant and a high insulation property and that may be reduced in film thickness. The thin film of strontium titanate, formed by sputtering at elevated temperatures in an oxygen atmosphere, may have optimum insulation properties of the relative dielectric constant of 200 and the insulation destruction withstand voltage of not less than 10V. With the use of the thin film of strontium titanate, it is possible to increase the capacitance per unit area to 10000 or more times that in case of using a resin film of 50 μm in thickness. In case it is desired to realize the same value of capacitance to generate a bandgap in a frequency range desired of the EBG structure, it is possible to drastically reduce the size of the conductor patch to 1/10000 or less.

As the material for the dielectric layer, compound oxides other than strontium titanate may also be used. Among these compound oxides, perovskite oxides, represented by the chemical formula ABO₃ (A and B being metal elements), such as barium titanate or lead titanate, pyroclore oxides, represented by the chemical formula A₂B₂O₇ (A and B being metal elements), Bi laminar ferroelectrics, such as SrBi₂Ta₂O₉, and compound oxides containing these as components exhibit higher dielectric constant values of several dozens to several hundreds in thin film states. The displacement of oxygen ions and that of ambient metal ions significantly contribute to the dielectric constant of the compound oxide, so that thin films with only a smaller number of defects may be formed in an oxygen atmosphere at elevated temperatures. The relative dielectric constant of oxides of Mg, Al, Si, Ti, Ta, Hf and Zr, among the materials of the dielectric layer, is higher than that of resin, as discussed above. Hence, these oxides lend themselves to increasing the capacitance or the capacitance per unit area to reduce the size of the conductor patches. To realize optimum insulation properties, it is preferred that those oxides are also generated in an oxygen atmosphere at elevated temperatures. The dielectric layer may again be formed by methods other than the sputtering method, such as by the CVD or sol-gel method. By these other methods, an optimum insulation film may be obtained by film forming or by heat treatment in an oxygen atmosphere at elevated temperatures not lower than 300° C.

To form the dielectric layer 23 in an oxygen atmosphere at elevated temperatures, the high melting point electrically conductive layer 33 and the intermediate layer 32 that make up the first conductive plane 22 are required to possess a preset thermal resistance. In the EBG structure 1c, Pt is used as a material of the high melting point electrically conductive layer 33, because Pt is stable in a temperature range of 300 to 600° C. necessary for forming the dielectric layer 23 and may form no low dielectric constant oxide layer even in an oxygen atmosphere. The material used for the high melting conductor layer is not limited to Pt and, from the perspective that the material is required to possess the preset thermal resistance, Pd, Ru or Ir may also be used. Although Pd, Ru or Ir may generate oxides in an oxygen atmosphere, the so formed oxides are conductors and do not deteriorate the effective capacitance of the capacitance element. As the high melting conductor layer, electrically conductive oxides, such as RuO₂ or IrO₂, which are electrically conductive oxides, may also be used as the high melting conductor layers.

First of all, the intermediate layer 32 is required to possess the function of providing for tight adherent properties. In the EBG structure 1c, the Ti layer operates as a tight adherent layer. In addition to Ti, Ta or Cr, for example, may be used as a material for the tight adherent layer. In the EBG structure 1c, the dielectric layer 23 is formed at an elevated temperature, specifically, at 450° C. In the state of the high temperature, silicon in the rigid substrate 21 is diffused into the intermediate layer 32. As a result, in the dielectric layer forming step, silicon is diffused through the inside of the intermediate layer or through the high melting conductor layer (Ti, Mo or Pt layer) so as to be precipitated on a Pt surface to form SiO₂. Since the relative dielectric constant of SiO₂ is 3.9, the effective dielectric constant is decreased to lower the capacitance. Hence, the intermediate layer 32 is required to possess the function as a diffusion barrier. This function as the diffusion barrier is played by the TiN layer. TaN or CrN may also be used for the diffusion barrier layer.

A Si wafer is used as the rigid substrate 21. In addition to Si, high dielectric constant metals, such as stainless steel, tungsten, molybdenum or titanium, may also be used as a material for the rigid substrate, as stated above. However, diffusion of a constituent element may cause the low dielectric constant oxide layer to be increased in thickness or may cause surface irregularities to be increased to render it difficult to produce a dielectric layer of a high dielectric constant and the optimum insulation performance. Hence, the diffusion barrier layer is needed even in case the above mentioned materials other than silicon are used as the rigid substrate material. Similarly to TiN, TaN, for example, exhibits a comparable effect as a diffusion barrier layer. If a semiconductor or metal is used for the rigid substrate, it is desirable to electrically interconnect the rigid substrate 21 and the first conductive plane 22. To electrically interconnect the rigid substrate 21 and the first conductive plane 22, it is sufficient that the operation of electrically interconnecting the rigid substrate 21 and the first conductive plane 22 is carried out in the course of the first conductive plane forming step. In the method for manufacturing the EBG structure 1c, removal of the native oxide film on the Si wafer surface corresponds to carrying out the above operation. In case the rigid substrate 21 and the first conductive plane 22 are electrically connected to each other, not only the intermediate layer 32 and the high melting point electrically conductive layer 33 but also the rigid substrate 21 itself performs the function of the first conductive plane. This is beneficial for reducing the loss in the first conductive plane. As the material for the rigid substrate 21, stable insulators, such as glass, sapphire, quartz or alumina, other than semiconductor or metal, may also be used. In this case, the role of the first conductive plane 22 is performed by the intermediate layer 32 and the high melting point electrically conductive layer 33. However, diffusion of component elements need not be taken into consideration. The intermediate layer 32 therefore is not needed for the above mentioned diffusion barrier layer and hence the latter may be simplified in structure.

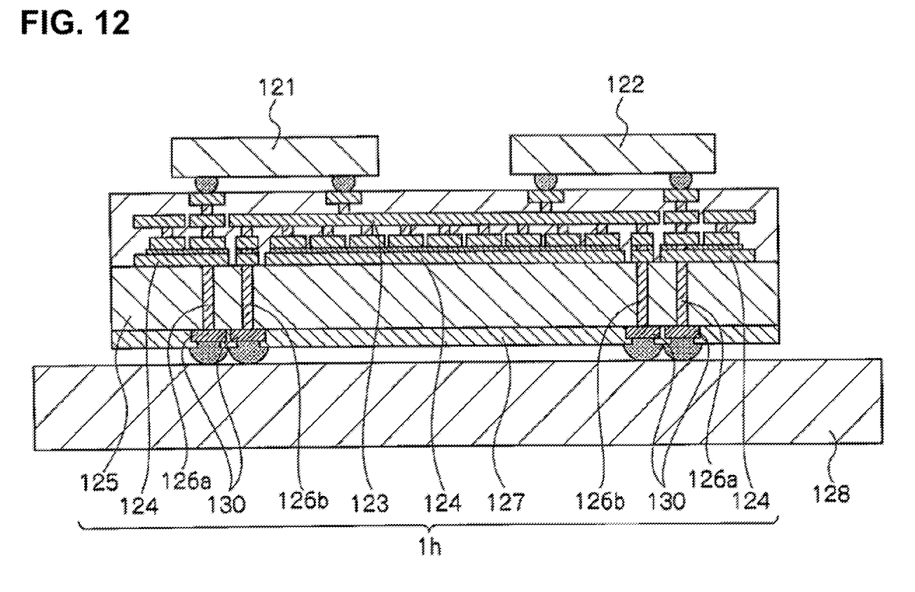

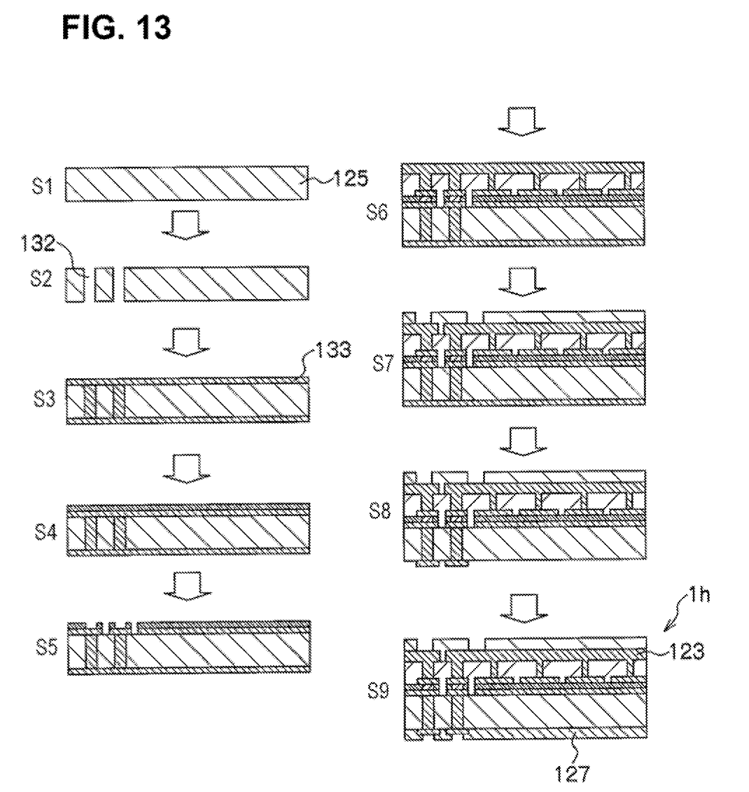

FIG. 12 is a schematic cross-sectional view showing Example 3 of the EBG structure of the present invention. FIG. 13 depicts a schematic process showing the manufacturing method for an EBG structure of FIG. 12 (Example 3). Specifically, FIG. 12 depicts a cross-sectional view showing an arrangement in which a rigid substrate, having embedded therein an EBG structure of the present invention, is used as an interposer. FIG. 13 depicts a schematic process for manufacturing an EBG structure formed as the interposer.

An EBG structure 1h includes backside pads 130 and through-electrodes 126a, 126b. The backside pads 130 are provided on one of both sides of a rigid substrate 125 which is not provided with a first conductive plane 124. The through-electrodes 126a, 126b are electrically connected to the backside pads 130 and provided extending through the rigid substrate 125 so as to be connected to a first conductive plane 124 or to a second conductive plane 123. Specifically, the through-electrode 126a is provided extending through the rigid substrate 125 so as to be electrically connected to the first conductive plane 124, whereas the through-electrode 126b is provided extending through the rigid substrate 125 so as to be electrically connected to the second conductive plane 123. It is observed that the first conductive plane 124 is provided as a ground plane, whereas the second conductive plane 123 is used as a power supply plane. The backside pad 130 is protected by a backside cover film 127.

The EBG structure 1h is featured by the following two points. First, referring to FIG. 12, external connection terminals are provided not only on the side of the rigid substrate 125, carrying thereon a variety of components of the EBG structure 1h, such as the first conductive plane 124, but on the back side of the rigid substrate 125 not carrying the components of the EBG structure. The external connection terminals are provided on the back side of the rigid substrate by providing the backside pads 130. Second, referring further to FIG. 12, the through-electrodes 126a, 126b are provided extending through the rigid substrate 125 to connect the respective elements of the EBG structure, specifically the first conductive plane 124 and the second conductive plane 123, and the external connection terminals as the backside pads 130 on the back side of the rigid substrate 125.

The EBG structure 1h is used as an interposer. The interposer is used as a chip carrier for packaging an LSI, and is packaged between LSIs 121, 122 and a printed circuit board 128. In FIG. 12, signal limes for the LSIs 121, 122 are omitted for convenience in explanation. By using the FBG structure 1h, it becomes possible to interrupt noise propagation to other devices inside and outside of the package in the direct neighborhood of the LSI 121 as the noise source. Moreover, by using the rigid substrate 125, control may be exercised to a thermal expansion coefficient close to that of the LSIs 121, 122. Thus, packaging of the multi-pin narrow-pitch LSIs, that is, LSIs having many pins and hence a narrow pin-to-pin pitch, may be facilitated. In addition, packaging of LSIs formed by fragile interlayer insulation films may also be facilitated.

The manufacturing method for the EBG structure 1h includes a step of boring a via through a rigid substrate and a backside pad forming step. The via boring step precedes a step of forming a first conductive plane forming step, and provides a through-via 132 provided extending through a rigid substrate 125. The backside pad forming step provides backside pads 130 on one of sides of the rigid substrate 125 that is not provided with the first conductive plane 124. Except the step of boring the via through the rigid substrate and the backside pad forming step, the manufacturing method for the EBG structure 1c, explained with reference to FIG. 5, may be used as appropriate.

The step of boring the via through the rigid substrate is a step preceding the first conductive plane forming step, and forms a through-via 132 in the rigid substrate 125 at the outset, as shown in FIG. 13. Specifically, the through-via 132 is bored by sandblasting through the bulk of the insulating rigid substrate 125. In the first conductive plane forming step, the through-hole 132 is filled with plating Cu, at the same time as Cu is deposited on the front and back sides of the rigid substrate 125. A Cu plating 133, charged into the through-hole 132, becomes the through-electrodes 126a, 126b. The Cu plating 133, formed on the surface of the rigid substrate 125, becomes the first conductive plane 124, while the Cu plating 133, deposited on the back side of the rigid substrate 125, is worked to provide the backside pads 130 in the backside pad forming step which will be explained subsequently.

The dielectric layer forming step, conductor patch forming step, interlayer insulating layer forming step and the second conductive plane/conductor forming step are then carried out in this order. The Cu plating 133 (Cu layer), formed on the rigid substrate 125, is to be the first conductive plane 124. A dielectric layer and so forth are deposited and worked to a desired shape. Specifically, the remaining elements of the EBG structure are sequentially formed in accordance with the above described process steps.

In the backside pad forming step, the Cu plating 133, the Cu layer on the back side of the rigid substrate 125, is worked to the shape of the backside pad 130. A backside cover film 127 is then formed to yield the EBG structure 1h. Meanwhile, the region on top of the through-electrode 126b, connected to the second conductive plane 123, is to be electrically isolated from the first conductive plane 124 at the time of forming the first conductive plane 124.

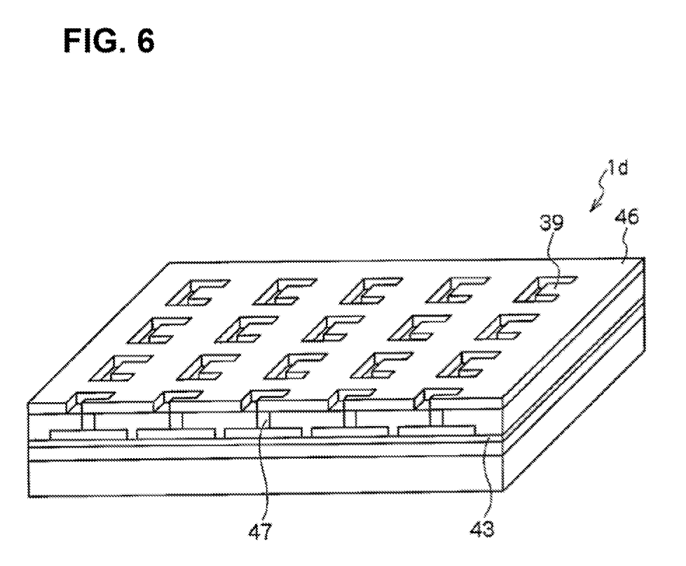

FIG. 6 is a schematic perspective view showing an Example 4 of the EBG structure of the present invention. In the EBG structure, not only capacitance increasing means but also inductance increasing means may be used for controlling the bandgap frequency range. FIG. 6 depicts a perspective view showing such EBG structure.

In an EBG structure 1d, an inductance element (linear inductor 39) is explicitly added to a second conductive plane 46. Specifically, a cut-out is formed in the second conductive plane 46 in the vicinity of a conductor 47 on the second conductive plane 46. The linear inductor 39 is connected between the conductor 47 and the second conductive plane 46. To obtain a desired inductance, a spiral inductor gives a meritorious effect comparable to that obtained with the linear inductor. The linear inductor 39 may give rise to surface irregularities, so that it is difficult to deposit, as an overlying layer, a dielectric layer which is thinner in thickness than an interconnection layer and which exhibits an optimum insulation performance. In the EBG structure 1d, an inductor element (linear inductor 39) is formed after forming the dielectric layer 43. Hence, there is no adverse effect on forming the dielectric layer 43.

(Filter Element, Printed Circuit Board and a Manufacturing Method for an EBG Structure for Application Thereto)

With the use of the present invention, the EBG structure, which has so far been formed in an area of several cm square on a printed circuit board, may appreciably be reduced in size. Typically, the EBG structure may be implemented to a size not larger than 1 cm square. It may thus be rendered a discrete component which may then be readily mounted at a desired position in electronic equipment. An Example of the present invention, in which the EBG structure of the present invention is applied to a filter element and to a printed circuit board with a filter element embedded therein, will now be described. Specifically, such a case where the EBG structure of the present invention is used as a power supply noise suppressing filter component will now be described.

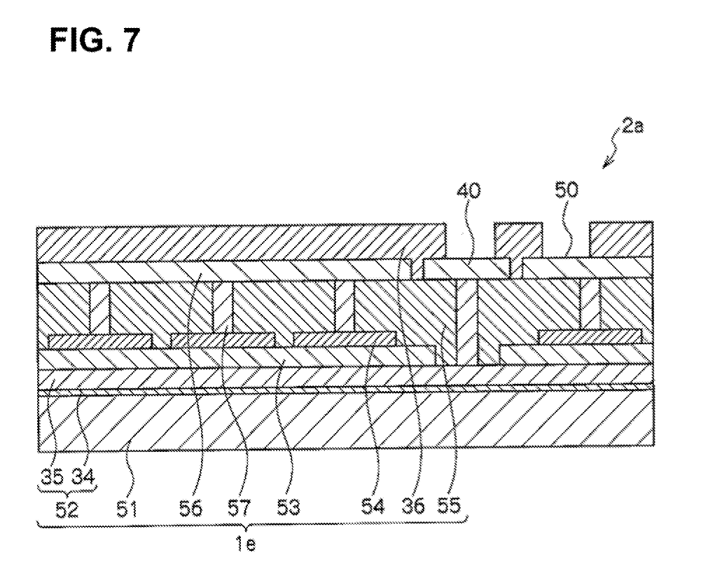

FIG. 7 depicts a schematic cross-sectional view showing an Example of a filter element according to the present invention. Specifically, such a structure of the external connection terminals is shown in FIG. 7 for a case where the filter element 2a is embedded in a device as a discrete component.

The filter element 2a includes an EBG structure 1e, a first external connection terminal 40 and a second external connection terminal 50. The first external connection terminal is connected to a first conductive plane 52 of the EBG structure 1e. The second external connection terminal is connected to a second conductive plane 56 of the EBG structure 1e.

The EBG structure 1e includes a rigid substrate 51, a first conductive plane 52 provided on the rigid substrate 51, and a dielectric layer 53 provided on the first conductive plane 52. The EBG structure 1e also includes a plurality of conductor patches 54 arrayed in a two-dimensional regular pattern on the dielectric layer 53. The EBG structure further includes an interlayer insulation film 55 deposited on the multiple conductor patches 54 and a second conductive plane 56 formed on the interlayer insulation film 55. The conductor patches 54 and the second conductive plane 56 are interconnected by multiple conductors 57 passed through the interlayer insulation film 55. The first conductive plane 52 includes a laminated structure made up of an intermediate layer 34 and a high melting point electrically conductive layer 35.

In the filter element 2a, an insulator is used for a rigid substrate 51. The dielectric layer 53, conductor patches 54 and the second conductive plane 56 are partially removed to provide a contact pad for the first conductive plane 52. A window is opened in the cover layer 36 to expose part of the contact pad of the first conductive plane 52. This forms a first external connection terminal 40 connecting to the first conductive plane 52. Another window is opened in the cover layer 36 to expose part of the second conductive plane 56. This forms a second external connection terminal 50 connecting to the second conductive plane 56. In the filter element 2a, a contact of the first conductive plane 52 (first external connection terminal 40) is formed in a region of the regular array of the conductor patches 54. However, such contact may be provided outside of the region of the regular array of the conductor patches 54. In the filter element 2a, the external connection pads, forming the first external connection terminal 40 and the second external connection terminal 50, are formed on one side of the filter element 2a, thus allowing for surface mounting.

Each one of the first external connection terminal 40 and the second external connection terminal 50 are provided in the filter element 2a. However, two or more of the first external connection terminals 40 and two or more of the second external connection terminals 50 may be provided in the filter element.

Since the filter element 2a uses the EBG structure 1e, the area of the filter element 2a may be reduced to less than 1 cm².

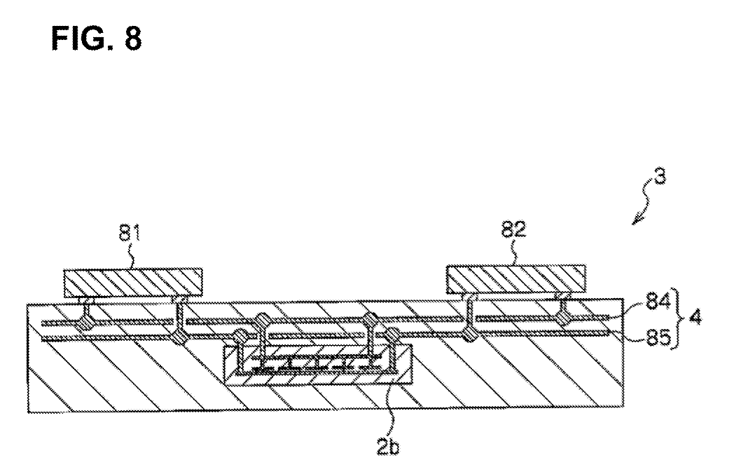

FIG. 8 depicts a schematic cross-sectional view of an Example of the printed circuit board 3 with an embedded filter element of the present invention. In more detail, in the printed circuit board 3 with the embedded the filter element, a power supply noise suppressive filter component, which is the embedded filter element 2b, is used as it is mounted in the inside of the printed circuit substrate 4.

The printed circuit board 3 with the embedded the filter element includes the embedded filter element 2b and a printed circuit substrate 4 in which the filter element 2h is embedded. A first external connection terminal of the filter element 2b is connected to a power supply plane 84 of the printed circuit substrate 4, and a second external connection terminal of the filter element 2b is connected to a ground plane 85 of the printed circuit substrate 4. Or, the first external connection terminal of the filter element 2b is connected to the ground plane 85 of the printed circuit substrate 4, and the second external connection terminal of the filter element 2b is connected to the power supply plane 84 of the printed circuit substrate 4.

More specifically, two conductive planes are embedded in the printed circuit board 3 so that these conductive planes are connected to the power supply plane 84 and to the ground plane 85. The embedding process may be carried out similarly to the process of embedding the LSIs or the chip components. In the printed circuit board 3, in which there is embedded the filter element, the filter element 2b is not surface mounted, but is embedded inside of the substrate. Hence, a device 81 that may be the noise source and a device 82 susceptible to noise may be mounted on the top of the printed circuit substrate 4. The printed circuit board may thus be made smaller in size than if the wiring of the printed circuit substrate 4 is used. Meanwhile, if the semiconductor or metal is used for the rigid substrate, which rigid substrate is to be a functional portion of the first conductive plane, external connection terminals are arranged on the top and the bottom of the filter element. It is thus possible to mount the filter element between the power supply plane 84 and the ground plane 85.

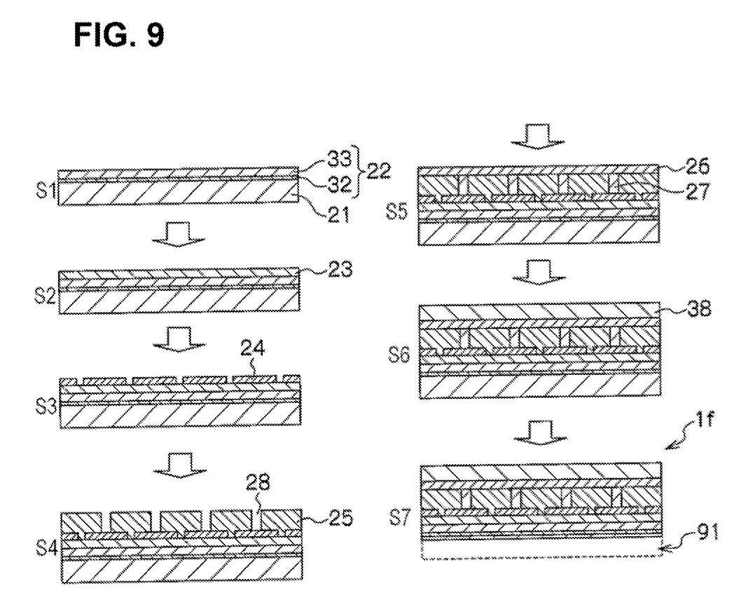

FIG. 9 depicts a schematic process showing an Example 4 of the manufacturing method for an EBG structure of the present invention. Specifically, FIG. 9 shows a schematic process for illustrating the manufacturing method for forming the EBG structure of the present invention to a shape suited for embedding in the inside of the printed circuit board.

For manufacturing the EBG structure 1f of the present invention, the manufacturing method for the EBG structure 1c, explained with reference to FIG. 5, is directly used up to the step of forming a cover layer 38 of resin next to the second conductive plane/conductor forming step. A step of thinning and removing the rigid substrate 21 is then performed. In this thinning/removing step, the rigid substrate 21 is thinned or removed by grinding or etching. As a result of this thinning/removing step, the rigid substrate 21 is reduced in thickness in an amount corresponding to the removed rigid substrate portion 91. However, the rigid substrate 21 is not completely removed even after the end of the thinning/removing step. That is, simply the rigid substrate 21 is reduced in thickness, such that it is not completely removed.

In the rigid substrate thinning/removing step, the rigid substrate 21 is ground or etched from its back side to reduce its thickness. The reason the rigid substrate is so ground or etched is that the EBG structure has been formed by buildup on the rigid substrate 21.

In the rigid substrate thinning/removing step, it is preferred that the rigid substrate 21 is thinned or partially removed so that the EBG structure 1f will be of a thickness not larger than 300 μm. If the overall thickness is not larger than 300 μm, the EBG structure may be mounted so as to be co-planar with a small-sized chip component in the course of the process step of fabricating a printed circuit board with an embedded component. It is thus possible to get the filter element embedded without addition of a particular process step.

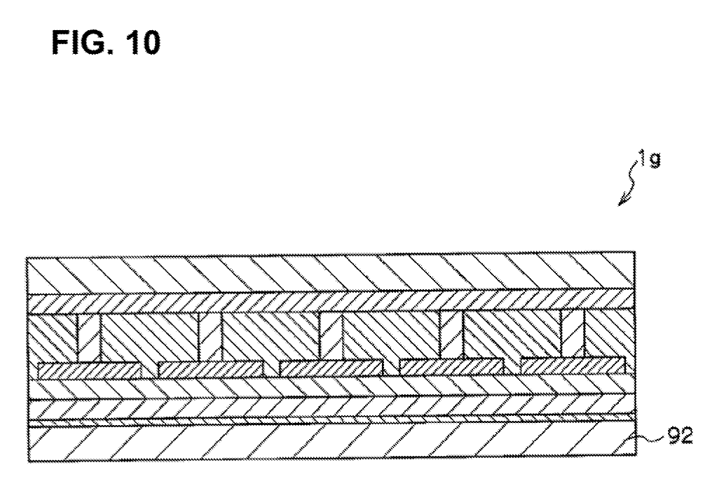

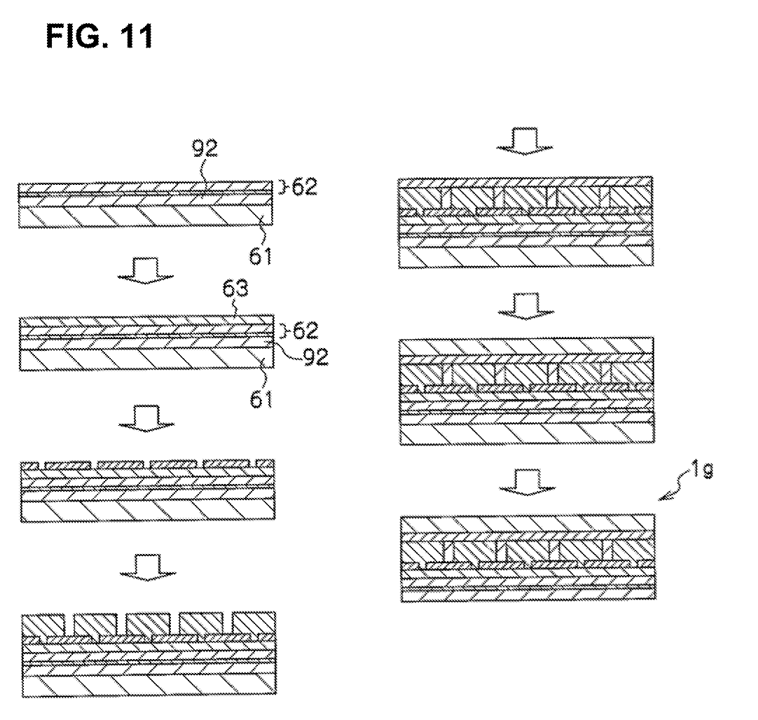

FIG. 10 depicts a schematic cross-sectional view showing an Example 5 of the EBG structure according to the present invention. FIG. 11 depicts a schematic process showing a manufacturing method for an EBG structure of the present invention (Example 5) shown in FIG. 10. Specifically, FIG. 10 depicts a cross-sectional view of the EBG structure, in which the EBG structure is reduced further in thickness for embedding in the inside of the substrate or arranged as a film-shaped component for embedding in a flexible board. FIG. 11 depicts a schematic process showing the manufacturing method of an EBG structure formed to the film-shaped component.

An EBG structure 1g includes a highly thermally resistant resin layer 92 between a rigid substrate 61 and a first conductive plane 62, as shown in FIG. 11. The rigid substrate 61 is ultimately removed. The highly thermally resistant resin layer 92 thus acts as a substrate for the EBG structure 1g, as shown in FIG. 10. Since the highly thermally resistant resin layer 92 is flexible, the EBG structure 1g may be obtained as a film-shaped product.

Referring to FIG. 11, the EBG structure 1g may be manufactured in accordance with the above described manufacturing method for the EBG structure except forming the first conductive plane 62 after coating the highly thermally resistant resin on the rigid substrate 61, and except performing the rigid substrate thinning/removing step after the second conductive plane/conductor forming step to remove the rigid substrate 61. It is observed that the rigid substrate thinning/removing step of removing the rigid substrate 61 by grinding or etching the rigid substrate 61 is carried out after the second conductive plane/conductor forming step. Specifically, a highly thermally resistant resin, such as polyimide, is coated on the rigid substrate 61, after which such members as the first conductive plane 62 and a dielectric layer 63 are sequentially deposited. Finally, the rigid substrate 61 in its entirety is removed by grounding or etching to yield the film-shaped EBG structure 1g whose bottom surface is covered with the highly thermally resistant resin layer 92.

The description of the EBG structure, filter element, printed circuit board with an embedded filter element, and the manufacturing method for the EBG structure, has been made in the foregoing. It is observed that the present invention is not limited to the Examples thereof described above and may be altered in many ways. Viz., the relative dielectric constant of the dielectric layer is preferably larger than that of the interlayer insulation film. The dielectric layer is preferably a metal oxide with a film thickness not larger than 1 μm and a relative dielectric constant of not less than 10 and desirably not less than 100.

In the manufacturing method for the EBG structure according to the present invention, the step of filling the via in the interlayer insulation film with a conductor and the step of forming the second conductive plane may be carried out as separate steps. Also, the step of forming the dielectric layer may be carried out under heating to not lower than 300° C.

### INDUSTRIAL APPLICABILITY

The EBG structure of the present invention, having a bandgap in a specified frequency rage, may be arranged as a device of a small size and a thin thickness that may be surface mounted on or embedded in a modular substrate, an interposer or a printed circuit board.

The particular exemplary embodiments or examples may be modified or adjusted within the gamut of the entire disclosure of the present invention, inclusive of claims, based on the fundamental technical concept of the invention. Further, a wide variety of combinations or selection of elements disclosed herein may be made within the framework of the claims. That is, the present invention may encompass various modifications or corrections that may occur to those skilled in the art in accordance with and within the gamut of the entire disclosure of the present invention, inclusive of claim and the technical concept of the present invention.

### EXPLANATION OF SYMBOLS

1a, 1b, 1c, 1d, 1e, 1f, 1g and 1h EBG structures
2a, 2b filter elements
3 printed circuit board with an embedded filter element
4 printed circuit board
11,21,51,61,125 rigid substrates
12, 22, 52, 62, 124 first conductive planes
13, 23, 43, 53, 63 dielectric layers
14, 24, 54 conductor patches
15, 25, 55 interlayer insulation films
16, 26, 46, 56, 123 second conductive planes
17, 27, 47, 57 conductors
18, 28 vias
21 capacitance elements
22 inductance elements
32, 34 intermediate layers
33, 35 high melting point electrically conductive layer
36 to 38 cover layers
39 linear inductor
40 first external connection terminal
50 second external connection terminal
81 device that may act as noise source
82 device susceptible to noise
84 power supply plane
85 ground plane
91 removed rigid substrate portion
92 highly thermally resistant resin layer
121, 122 LSIs
126a, 126b through-electrodes
127 backside cover film
128 printed circuit board
130 backside pads
132 through-via
133 Cu plating
S1 to S9 process steps

What is claimed is:

1. An electromagnetic bandgap structure comprising:
a rigid substrate, a first conductive plane provided on said rigid substrate, a dielectric layer provided on said first conductive plane, a plurality of conductor patches arrayed in a two-dimensional regular pattern on said dielectric layer, an interlayer insulation film provided on said conductor patches, and a second conductive plane provided on said interlayer insulation film, wherein
said conductor patches and said second conductive plane are interconnected by a plurality of conductors provided extending through the bulk of said interlayer insulation film.

2. The electromagnetic bandgap structure according to claim 1, wherein said dielectric layer is not larger than 1 μm in thickness.

3. The electromagnetic bandgap structure according to claim 1, wherein
said dielectric layer contains an oxide of at least one element selected from the group consisting of Mg, Al, Si, Ti, Ta, Hf and Zr as a principal component.

4. The electromagnetic bandgap structure according to claim 1, wherein
said dielectric layer contains a compound oxide of metal elements as a principal component.

5. The electromagnetic bandgap structure according to claim 1, wherein
said first conductive plane includes, when looking from the side said rigid substrate, an intermediate layer and a high melting point electrically conductive layer, in this order; said intermediate layer being provided with at least one layer formed of at least one material selected from the group consisting of Ti, Ta, Cr, a nitride of Ti, a nitride of Ta and a nitride of Cr; said high melting point electrically conductive layer being formed on said intermediate layer and provided with at least one layer formed of at least one element selected from the group consisting of Pt, Pd, Ru and Ir.

6. The electromagnetic bandgap structure according to claim 1, wherein
said rigid substrate is formed of a conductor or a semiconductor.

7. The electromagnetic bandgap structure according to claim 6, wherein
said rigid substrate and said first conductive plane are electrically connected to each other.

8. The electromagnetic bandgap structure according to claim 6, wherein
said conductor or semiconductor is at least one selected from the group consisting of Si, GaAs, stainless steel, tungsten, molybdenum and titanium.

9. The electromagnetic bandgap structure according to claim 1, wherein
said rigid substrate is formed of at least one material selected from the group consisting of glass, sapphire, quartz and alumina.

10. The electromagnetic bandgap structure according to claim 1, further comprising:
a backside pad provided on one of both sides of said rigid substrate that is not provided with said first conductive plane; and
a through-electrode electrically connected to said backside pad; said through-electrode being provided extending through the bulk of said rigid substrate so as to be connected to said first conductive plane or to said second conductive plane.

11. A filter element comprising:
an electromagnetic bandgap structure according to claim 1,
a first external connection terminal connected to said first conductive plane of said electromagnetic bandgap structure; and
a second external connection terminal connected to said second conductive plane of said electromagnetic bandgap structure.

12. The filter element according to claim 11, wherein
there are provided two or more of said first external connection terminals and two or more of said second external connection terminals.

13. The filter element according to claim 11, wherein
said filter element is smaller than 1 cm² in area.

14. A printed circuit board having an embedded filter element comprising:
the filter element according to claim 11 and a printed circuit board having said filter element embedded therein; wherein
said first external connection terminal of said filter element is connected to a power supply plane of said printed circuit board and said second external connection terminal of said filter element is connected to a ground plane of said printed circuit board; or
said first external connection terminal of said filter element is connected to said ground plane of said printed circuit board and said second external connection terminal of said filter element is connected to said power supply plane of said printed circuit board.

15. A method for manufacturing an electromagnetic bandgap structure, comprising
forming a first conductive plane on a rigid substrate;
forming a dielectric layer on said first conductive plane;
forming a plurality of conductor patches arrayed in a regular two-dimensional pattern on said dielectric layer;
forming an interlayer insulation layer on said conductor patches; and
forming a second conductive plane on said interlayer insulation layer and forming a plurality of through-conductors arranged in said interlayer insulation layer to interconnect said conductor patches and said second conductive plane.

16. The method for manufacturing an electromagnetic bandgap structure according to claim 15, wherein,
in said dielectric layer forming step, the thickness of said dielectric layer is set so as to be not larger than 1 μm.

17. The method for manufacturing an electromagnetic bandgap structure according to claim 15, wherein,
in said dielectric layer forming step, said dielectric layer is formed using, as a principal component, an oxide of at least one element selected from the group consisting of Mg, Al, Si, Ti, Ta, Hf and Zr.

18. The method for manufacturing an electromagnetic bandgap structure according to claim 15, wherein,
in said dielectric layer forming step, said dielectric layer is formed using a compound oxide of metal elements as a principal component.

19. The method for manufacturing an electromagnetic bandgap structure according to claim 15, wherein,
in said dielectric layer forming step, said dielectric layer is formed by at least one method selected from the group consisting of a sputtering method, a CVD method, a sol/gel method, an aerosol deposition method and a spin coating method.

20. The method for manufacturing an electromagnetic bandgap structure according to claim 15, wherein
said first conductive plane forming step includes an intermediate layer forming step and a high melting point electrically conductive layer forming step; said intermediate layer and said high melting point electrically conductive layer being formed in this order when looking from the rigid substrate side; said intermediate layer forming step forming an intermediate layer provided with at least one layer formed of at least one material selected from the group consisting of Ti, Ta, Cr, a nitride of Ti, a nitride of Ta and a nitride of Cr; said high melting point electrically conductive layer being formed on said intermediate layer and being provided with at least one layer formed of at least one element selected from the group consisting of Pt, Pd, Ru and Ir.

21. The method for manufacturing an electromagnetic bandgap structure according to claim 15, wherein
said rigid substrate is formed of a conductor or a semiconductor.

22. The method for manufacturing an electromagnetic bandgap structure according to claim 21, wherein, in said first conductive plane forming step, said rigid substrate and said first conductive plane are electrically connected to each other.

23. The method for manufacturing an electromagnetic bandgap structure according to claim 21, wherein
said conductor or semiconductor is at least one selected from the group consisting of Si, GaAs, stainless steel, tungsten, molybdenum and titanium.

24. The method for manufacturing an electromagnetic bandgap structure according to claim 15, wherein
said rigid substrate is formed of at least one material selected from the group consisting of glass, sapphire, quartz and alumina.

25. The method for manufacturing an electromagnetic bandgap structure according to claim 15, wherein,
in said first conductive plane forming step, said first conductive plane is formed after coating a highly thermally resistant resin on said rigid substrate.

26. The method for manufacturing an electromagnetic bandgap structure according to claim 15, further comprising:
a rigid substrate thinning/removing step of thinning or removing said rigid substrate by grinding o′ r etching after said second conductive plane/conductor forming step.

27. The method for manufacturing an electromagnetic bandgap structure according to claim 26, wherein,
in said rigid substrate thinning/removing step, said rigid substrate is thinned or removed so that the thickness of said electromagnetic bandgap structure will be not larger than 300 μm.

28. The method for manufacturing an electromagnetic bandgap structure according to any claim 15, further comprising:
boring a through-via in said rigid substrate, said step of boring the through-via in said rigid substrate being carried out before said first conductive plane forming step; said step of boring a through-via in said rigid substrate forming said through-via in said rigid substrate; and
forming a backside pad on one of both sides of said rigid substrate that is not provided with said first conductive plane.
